(19) United States
(12) Patent Application Publication
(10) Pub. No.: US 2010/0073203 A1
(43) Pub. Date: Mar. 25, 2010

(54) WORLDs SMALLEST KEYBOARD AND CONTROL MEANS

(76) Inventor: James W. Burrell, IV, Union, NJ (US)

Correspondence Address: Ezra Sutton, P.A.;Suite 201, Plaza 9, 900 Route 9, Woodbridge, NJ, 07095-1024, US

(21) Appl. No.: 12/235,984

(22) Filed: Sep. 23, 2008

(51) Int. Cl. H03M 11/04

(52) U.S. Cl. 341/22

(57) ABSTRACT

This invention relates to methods of using a 360° directional movement sensor as a pointing device in eight cardinal point directions or in a downward direction for producing alphabetic data characters, data characters, a space, numbers, punctuation, symbols, control and functions, preferably activated by the left or right thumb. This invention also relates to methods of producing data using a simultaneous data entry method and/or a sequential data entry utilizing a 3600 directional movement sensor as a pointing device in eight cardinal point directions or in a downward direction combined with three or six additional sensors. This invention produces alphabetic data characters, data characters, a space, numbers, punctuation, symbols, control and functions using a 360° directional movement sensor as a pointing device in eight cardinal point directions or in a downward direction combined with three or six additional sensors. Using the pointing device produces a number, a first data character of three or four data characters or multiple data characters. Activating the pointing device once produces a first data character, twice produces a second data character, thrice produces a third data character, four times produces a fourth data character, five times produces a fifth data character, six times produces a sixth data character, seven times produces a seventh data character, eight times or more produces additional data characters. The pointing device combined with at least three additional sensors provide for simultaneous or sequential sensor activations, reducing the frequency of individual, simultaneous or sequential sensor activations. The pointing device combined with six additional sensors provide for simultaneous or sequential sensor activations which require fewer sensor activations than using only three additional sensors.

### FIELD OF THE INVENTION

The present invention relates to a method of using a 360° directional movement sensor with downward activation capabilities pointing device in eight cardinal point directions and in a downward direction for producing alphabetic data characters, data characters, a space, numbers, punctuation, symbols, control and functions, preferably activated by the left or right thumb. Additional sensors and at least three additional sensors are used for simultaneous or sequential activation to provide a reduction in the number of key activations for producing alphanumeric data and a space. Six additional sensors are used for simultaneous or sequential activation to provide an even greater reduction in the number of key activations for producing alphanumeric data, a space, punctuation, symbols, control and functions.

### BACKGROUND OF THE INVENTION

Since the introduction of keyboards for producing alphanumeric data more than a hundred years ago, every number and alphabetic character was assigned its own key. Uppercase capital letters were produced using a shift key. Attempts to reduce the keyboard's size and the number of sensors used to produce alphanumeric data required using keyboards where each key produces more than one alphanumeric character. The least amount of sensors used to produce alphanumeric data in the well known prior art uses seven sensors, eight sensors or twelve sensors. There have also been keyboards using five and ten sensors, but they were never adopted into mainstream use. The following prior art references, which the inventor is aware of, are distinctly different from the present invention described in this patent application. The seven key keyboard used to produce six dot braille uses a chordic data entry method on six sensors and a seventh key to produce a space by the left or right thumbs. The eight key keyboard is used to produce six dot braille and eight dot braille. It uses a chordic data entry method on six or eight sensors. When producing six dot braille, the seventh and eighth keys are used by the left or right thumbs to produce a space. When the eight key keyboard is used to produce eight dot braille, it uses a chordic data entry method on all eight sensors.

Another eight key keyboard used to produce eight dot braille using an eight key chordic data entry method is found in U.S. Pat. No. 5,993,089 issued on Nov. 30, 1999 to Burrell, IV, titled “8-BIT BINARY CODE FOR USE AS AN 8-DOT BRAILLE ARRANGEMENT AND DATA ENTRY SYSTEM AND METHOD FOR 8-KEY CHORDIC BINARY KEYBOARDS”. Burrell, IV teaches a chordic data entry system and method to enter all Latin based alphabets and all computer data using only eight sensors. The keyboard can also be adapted to enter all alphabets used throughout the world and all Unicode data.

The twelve key keyboard uses a phone keypad to produce alphanumeric data. Alphabetic characters are produced using sensors 1 through 9 or sensors 2 through 9. The fastest and most efficient method of producing alphanumeric data requiring the least amount of key activations on a phone is found in U.S. Pat. No. 6,043,761 issued on Mar. 28, 2000 to Burrell, IV, titled “METHOD OF USING A NINE KEY ALPHANUMERIC BINARY KEYBOARD COMBINED WITH A THREE KEY BINARY CONTROL KEYBOARD”, U.S. Pat. No. 6,184,803 issued on Feb. 6, 2001 to Burrell, IV, titled “NINE KEY ALPHANUMERIC BINARY KEYBOARD COMBINED WITH A THREE KEY BINARY CONTROL KEYBOARD AND COMBINATIONAL CONTROL MEANS” and in U.S. Pat. No. 6,232,892 issued on May 15, 2001 to Burrell, IV, titled “METHOD OF USING A NINE KEY ALPHANUMERIC BINARY KEYBOARD COMBINED WITH A THREE KEY BINARY CONTROL KEYBOARD”. A partial demonstration of the Burrell, IV twelve key keyboard can be found on the www.phonekeyboard.com website along with the data entry statistics. The fastest and most efficient method of producing alphanumeric data requiring the least amount of key activations using nine keys or a menu key is found in U.S. patent application Ser. No. 12/202,702 filed on Sep. 2, 2008 titled “NINE SENSOR DATA ENTRY KEYBOARD AND CONTROL MEANS”. A partial demonstration of the Burrell, IV nine key keyboard can be found on the www.thumbkeyboard.com website. Other slower twelve key keyboard alphanumeric data entry methods requiring the more key activations are T9 introduced by Tegic, iTAP introduced by Motorola and eZiText introduced by ZI Corp.

Many solutions to improve many of the existing prior art problems have been made, but many are not well suited for the blind community, the deaf-blind community and for an individual needing to enter alphabetic data into a data entry device without looking at the keyboard entry device. A method of alphanumeric data entry into a data entry keyboard device which does not require visual assistance is needed. The invention disclosed in this patent application fulfills this need.

### SUMMARY OF THE INVENTION

The present invention produces alphabetic data characters, data characters, a space, numbers, punctuation, symbols, control and functions using a pointing device in eight cardinal point directions or downward . The use of a pointing device in eight cardinal point directions or downward activated by only one finger, preferably the thumb digit, produces the world's smallest data entry keyboard. Moving the pointing device in eight cardinal point directions or downward once, twice, thrice, etc. produces the desired data. This method of producing data or text messaging can be used on a pointing device with downward activation capabilities. Combining the pointing device with the applicant's three issued patents; U.S. Pat. No. 6,043,761, U.S. Pat. No. 6,184,803, U.S. Pat. No. 6,232,892, and pending application produces a method of text messaging using any pointing device faster and smaller than all prior art devices using any disclosed prior art. The present invention can use any of the prior art text messaging methods, but the applicant's three issued patents and pending patent are the preferred input method due to the reduction in sensor activations required to produce data.

One preferred embodiment of the present invention uses a method of using a pointing device in eight cardinal point directions or downward for producing alphabetic data characters, data characters, a space, numbers, punctuation, symbols, control and functions. Moving the pointing device downward or in eight cardinal point directions once produces the first preferably left position data, twice produces the second preferably middle position data, thrice produces the third preferably right position data, etc. Alternatively, moving the pointing device in eight cardinal point directions or downward combined with the simultaneous activation of or followed by the sequential activation of a first left position preferred asterisk [*] sensor produces the first preferably left position data, activation of a second middle position preferred zero [0] sensor produces the second preferably middle position data, or activation of a third right position preferred number [#] sensor produces the third preferably right position data. Secondary activation of the second activated sensor produces an upper-case letter.

Activating the pointing device in eight cardinal point directions or downward eight times or more produces even more data characters, control or functions. Programming the device to produce the user's preferred data characters using preferred key activations is also possible.

Another preferred embodiment of the present invention uses a method of using a pointing device for producing numbers one through nine, at least twenty-six data characters or letters of an alphabet and a space, punctuation and symbols using a pointing device in eight cardinal point directions or downward. Moving the pointing device in eight cardinal point directions or downward once produces numbers one through nine, twice produces the first preferably left position data, thrice produces the second preferably middle position data and four times produces the third preferably right position data, etc. Alternatively, moving the pointing device in eight cardinal point directions or downward combined with the simultaneous activation of or followed by the sequential activation of a first left position preferred asterisk [*] sensor produces the first preferably left position data, activation of a second middle position preferred zero [0] sensor produces the second preferably middle position data, or activation of a third right position preferred number [#] sensor produces the third preferably right position data. Secondary activation of the second sensor, produces an upper-case letter.

Activating the pointing device in eight cardinal point directions or downward eight times or more produces even more data characters, control or functions. Programming the device to produce the user's preferred data characters using preferred key activations is also possible.

Another preferred embodiment of the present invention uses a method of using a pointing device in eight cardinal point directions or downward for producing numbers one through nine, at least twenty-six data characters or letters of an alphabet and a space, punctuation and symbols. Moving the pointing device in eight cardinal point directions or downward once produces numbers one through nine. Alternatively, moving the pointing device in eight cardinal point directions or downward combined with the simultaneous activation of or followed by the sequential activation of a first left position preferred asterisk [*] sensor produces the first preferably left position data, activation of a second middle position preferred zero [0] sensor produces the second preferably middle position data, or activation of a third right position preferred number [#] sensor produces the third preferably right position data. Secondary activation of the second activated sensor produces an upper-case letter. Moving the pointing device in eight cardinal point directions or downward combined with the simultaneous activation of or followed by the sequential activation of a first left position sensor ([1], [4] or [7]) produces the left position data, activation of a second middle position sensor ([2], [5] or [8]) produces the middle position data, or activation of a third right position sensor ([3], [6] or [9]) produces the right position data.

Extra punctuation marks, symbols and functions are produced by activating the pointing device in eight cardinal point directions or downward more than one time.

Alternatively, any letter data, numeric data, punctuation data, symbol data or any other type of data or character substitution can be made or used for the present invention's described text input methods and alternative preferred embodiments.

In another preferred embodiment of the present invention, when using the pointing device in eight cardinal point directions or downward to produce data on a device or cell phone, activating any sensor other than the pointing device in eight cardinal point directions or downward enters the entered data for the production of the next data character located on the same sensor as the previously entered data character.

In another preferred embodiment of the present invention, moving the pointing device in eight cardinal point directions or downward combined with the simultaneous activation of or followed by the sequential activation of a first left position preferred [1] [4], [7] or [*] sensor produces the first preferably left position data, activation of a second middle position preferred [2], [5], [8] or [0] sensor produces the second preferably middle position data, or activation of a third right position preferred [3], [6], [9] or [#] sensor produces the third preferably right position data.

In another preferred embodiment of the present invention, when using the pointing device in eight cardinal point directions or downward to produce data on a device or cell phone, activating the first left position preferred asterisk [*] sensor when using only the centrally located sensor surrounded by eight adjacent sensors to produce alphabetic data, while in an alphabetic multi-tap mode, produces an upper-case data character.

In another preferred embodiment of the present invention, when using the pointing device in eight cardinal point directions or downward to produce data on a device or cell phone, activating the first left position preferred asterisk [*] sensor once produces a period “.”, activating the second middle position preferred zero [0] sensor once produces a space “ ”, activating the third right position preferred number [#] sensor once produces a hyphen “-”.

In another preferred embodiment of the present invention, numbers are produced by activating one of the ten numbered sensors.

In another preferred embodiment of the present invention, to produce a backspace while in the number mode, the third right position preferred number [#] sensor is activated once, when it is not followed by the sequential activation of a first left preferred asterisk [*] sensor or a second middle preferred zero [0] sensor.

In another preferred embodiment of the present invention, activation of the third right position preferred number [#] sensor three times, while in the alphanumeric mode, produces the “ENTER/RETURN/SEND” function.

In another preferred embodiment of the present invention, activation of the first left position preferred asterisk [*] sensor, while in the number mode, when not followed by the sequential activation of middle preferred zero [0] sensor or the activation of the third right position preferred number [#] sensor, exits the number mode and enters an alphabet mode.

In another preferred embodiment of the present invention, activation of the first left position preferred asterisk [*] sensor followed by the secondary activation of the first left position preferred asterisk [*] sensor, when not followed by the sequential activation of middle preferred zero [0] sensor or the activation of the third right position preferred number [#] sensor, while in the number mode, exits the number mode and enters a two sensor lower-case alphabet mode and a three sensor upper-case alphabet mode, where the secondary activation of the second sensor produces the upper-case character.

In another preferred embodiment of the present invention, activation of the second middle position preferred zero [0] sensor two times, while in an alphabetic mode, produces the “TAB” function.

In another preferred embodiment of the present invention, activation of the first left position preferred asterisk [*] sensor, while in an alphabetic mode, followed by the first left position preferred asterisk [*] sensor, deletes the previously-entered bit of data, otherwise known as the backspace.

In another preferred embodiment of the present invention, activation of the first left position preferred asterisk [*] sensor three times, while in an alphabetic mode, deletes the previously entered word.

In another preferred embodiment of the present invention, activation of the first left position preferred asterisk [*] sensor, while in an alphabetic mode, combined with the simultaneous activation of or followed by the sequential activation of the second middle position preferred zero [0] sensor produces a period “•”.

In another preferred embodiment of the present invention, activation of the first left position preferred asterisk [*] sensor, while in the alphabetic mode, combined with the simultaneous activation of or followed by the sequential activation of the activation of the third right position preferred number [#] sensor enters a one-time use punctuation mode, followed by the desired punctuation data sensor representation of the ten sensors numbered one [1] through zero [0].

In another preferred embodiment of the present invention, activation of the third right position preferred number [#] sensor combined with the simultaneous activation of or followed by the sequential activation of the second middle position preferred zero [0] sensor, while in the alphabetic mode, returns the keyboard to the number mode.

It is an object of the present invention to provide a complete data entry method using a pointing device in eight cardinal point directions or downward.

It is another object of the present invention to provide a simultaneous data entry method using a pointing device in eight cardinal point directions or downward combined with the simultaneous activation of three or six other sensors.

Finally, it is another object of the present invention to provide a sequential data entry method using a pointing device in eight cardinal point directions or downward combined with the sequential activation of three or six other sensors.

The present invention and many preferred embodiments of the present invention all use a centrally located sensor surrounded by eight adjacent sensors.

These and other objects, features and advantages of the present invention are provided within this patent application and will be better understood in connection with the following drawings and descriptions of the preferred embodiments. Additional objects of the present invention will become apparent as the description proceeds.

It is to be understood that the present invention is not limited in its application to the details of construction and to the arrangements of the components set forth in the following description or illustrated in the drawings. The present invention is capable of other embodiments and of being practiced and carried out in various ways. It should be also understood that the phraseology and terminology used in this patent application are for the purpose of describing and claiming the present invention and should not be regarded as limiting.

### DESCRIPTION OF THE DRAWINGS

For a better understanding of the invention as well as other objects, features and advantages thereof, reference is made to the following detailed description to be read in conjunction with the accompanying drawings, wherein:

FIG. 1 shows a top view of the present invention, depicting a circular shaped 360° directional movement sensor with downward activation capabilities used as an eight cardinal point direction pointing device with a downward activation capability.

FIG. 2 shows a top view of the present invention, depicting a circular shaped 360° directional movement sensor with downward activation capabilities used as an eight cardinal point direction pointing device with a downward activation capability and surrounded by eight cardinal point direction tactile protrusions positioned in eight cardinal point directions and preferably triangular shaped.

FIG. 3 shows a top view of the present invention, depicting an eight pointed star shaped 360° directional movement sensor with downward activation capabilities used as an eight cardinal point direction pointing device with a downward activation capability.

FIG. 4 shows a top view of the present invention, depicting an octagonal shaped 360° directional movement sensor with downward activation capabilities used as an eight cardinal point direction pointing device with a downward activation capability.

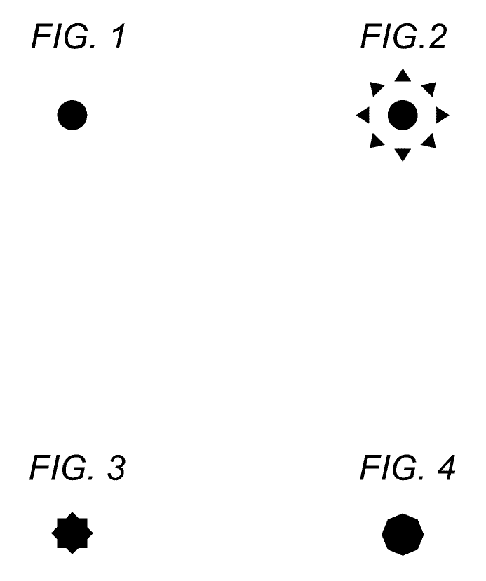

All of the preferred embodiments of the 360° directional movement sensor with downward activation capabilities also preferably have a protruding tactile surface or a dimple centrally located in the center on the top of the 360° directional movement sensor except when the 360° directional movement sensor is a trackball type of device or device where a protruding tactile surface or dimple is unfeasible.

### DETAILED DESCRIPTION OF THE PREFERRED EMBODIMENT

In order too more fully understand the invention, during the course of this description, the world's smallest keyboard using the one sensor keyboard invention and preferred embodiments, will be labeled and explained to easily identify like elements according to the different figures which illustrate the invention. Additional objects of the present invention will become apparent as the description proceeds.

In the telephone industry, it is well known that the depression of any given sensor on the telephone keypad generates one of twelve pairs of audio tones on the “touch tone” phone, or its digital data counterpart on a digital phone. In the cell phone industry, it is well known that the text messaging standard uses a method of multi-tap to produce data. This invention takes advantage of the applicant's three issued patents; U.S. Pat. No. 6,043,761, U.S. Pat. No. 6,184,803 and U.S. Pat. No. 6,232,892, to produce a space on the [1] sensor or on the [0] sensor and the fact that all prior art (T9, iTAP and eZiText) programmed cell phones use the zero [0] sensor or the number [#] sensor to produce a space on cell phone keypads. This invention also takes advantage of the applicant's pending patent application Ser. No. 12/202,702 filed on Sep. 2, 2008.

When any device is in the text messaging mode, the present invention produces at least twenty-six letters or characters, a space, numbers, punctuation and symbols using a 360° directional movement sensor with downward movement or activation capabilities which is also used for movement in eight cardinal point directions. The use of a 360° directional movement sensor with downward movement or activation capabilities activated by only one finger, preferably the thumb digit, produces the world's smallest data entry keyboard. Activating a 360° directional movement sensor once, twice, thrice, etc. produces the desired data. Moving the 360° directional movement sensor once, twice, thrice, etc. in eight cardinal point directions or downward produces the desired data. This method of producing data or text messaging can be used on a large or small trackball cursor pointing device with downward activation capabilities, on a 360° pointing device with downward activation capabilities or on any device with eight cardinal point movement directions with downward activation capabilities. Combining the world's smallest keyboard with the applicant's three issued patents; U.S. Pat. No. 6,043,761, U.S. Pat. No. 6,184,803, U.S. Pat. No. 6,232,892 and pending patent application Ser. No. 12/202,702 filed on Sep. 2, 2008 produces a method of text messaging on any device faster than all prior art devices using any disclosed prior art. The present invention can use any of the prior art text messaging methods, but the applicant's three issued patents and pending patent application are the preferred input method due to the reduction in sensor activations required to produce data. The 360° pointing device with downward activation capabilities will be referred to as a pointing device in the following description.

One preferred embodiment of the present invention includes:

A method of using a pointing device for producing alphabetic data characters, data characters, a space, numbers, punctuation, symbols, control and functions using a 360° pointing device with downward activation capabilities. Moving a pointing device in eight cardinal point directions or downward once produces the first preferably left position data, twice produces the second preferably middle position data and thrice produces the third preferably right position data, etc. Alternatively, moving a pointing device in eight cardinal point directions or downward combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second activated sensor produces an upper-case letter.

The “a” is produced by moving the pointing device in a north cardinal point direction once or by moving the pointing device in a north cardinal point direction once combined with the simultaneous activation of or followed by the sequential activation of the first left position preferred asterisk [*] sensor. Activating the first left position preferred asterisk [*] sensor twice produces an upper-case “A”.

The “b” is produced by moving the pointing device in a north cardinal point direction twice or by moving the pointing device in a north cardinal point direction once combined with the simultaneous activation of or followed by the sequential activation of the second middle position preferred zero [0] sensor. Activating the second middle position preferred zero [0] sensor twice produces an upper-case “B”.

The “c” is produced by moving the pointing device in a north cardinal point direction thrice or by moving the pointing device in a north cardinal point direction once combined with the simultaneous activation of or followed by the sequential activation of the third right position preferred number [#] sensor. Activating the third right position preferred number [#] sensor twice produces an upper-case “C”.

The “d” is produced by moving the pointing device in a north-east cardinal point direction once or by moving the pointing device in a north-east cardinal point direction once combined with the simultaneous activation of or followed by the sequential activation of the first left position preferred asterisk [*] sensor. Activating the first left position preferred asterisk [*] sensor twice produces an upper-case “D”.

The “e” is produced by moving the pointing device in a north-east cardinal point direction twice or by moving the pointing device in a north-east cardinal point direction once combined with the simultaneous activation of or followed by the sequential activation of the second middle position preferred zero [0] sensor. Activating the second middle position preferred zero [0] sensor twice produces an upper-case “E”.

The “f” is produced by moving the pointing device in a north-east cardinal point direction thrice or by moving the pointing device in a north-east cardinal point direction once combined with the simultaneous activation of or followed by the sequential activation of the third right position preferred number [#] sensor. Activating the third right position preferred number [#] sensor twice produces an upper-case “F”.

The “g” is produced by moving the pointing device in a west cardinal point direction once or by moving the pointing device in a west cardinal point direction once combined with the simultaneous activation of or followed by the sequential activation of the first left position preferred asterisk [*] sensor. Activating the first left position preferred asterisk [*] sensor twice produces an upper-case “G”.

The “h” is produced by moving the pointing device in a west cardinal point direction twice or by moving the pointing device in a west cardinal point direction once combined with the simultaneous activation of or followed by the sequential activation of the second middle position preferred zero [0] sensor. Activating the second middle position preferred zero [0] sensor twice produces an upper-case “H”.

The “I” is produced by moving the pointing device in a west cardinal point direction thrice or by moving the pointing device in a west cardinal point direction once combined with the simultaneous activation of or followed by the sequential activation of the third right position preferred number [#] sensor. Activating the third right position preferred number [#] sensor twice produces an upper-case “I”.

The “j” is produced by moving the pointing device downward once or by moving the pointing device downward once combined with the simultaneous activation of or followed by the sequential activation of the right preferred asterisk [*] sensor. Activating the first left position preferred asterisk [*] sensor twice produces an upper-case “J”.

The “k” is produced by moving the pointing device downward twice or by moving the pointing device downward once combined with the simultaneous activation of or followed by the sequential activation of the right preferred zero [0] sensor. Activating the second middle position preferred zero [0] sensor twice produces an upper-case “K”.

The “I” is produced by moving the pointing device downward thrice or by moving the pointing device downward once combined with the simultaneous activation of or followed by the sequential activation of the third right position preferred number [#] sensor. Activating the third right position preferred number [#] sensor twice produces an upper-case “L”.

The “m” is produced by moving the pointing device in an east cardinal point direction once or by moving the pointing device in an east cardinal point direction once combined with the simultaneous activation of or followed by the sequential activation of the first left position preferred asterisk [*] sensor. Activating the first left position preferred asterisk [*] sensor twice produces an upper-case “M”.

The “n” is produced by moving the pointing device in an east cardinal point direction twice or by moving the pointing device in an east cardinal point direction once combined with the simultaneous activation of or followed by the sequential activation of the second middle position preferred zero [0] sensor. Activating the second middle position preferred zero [0] sensor twice produces an upper-case “N”.

The “o” is produced by moving the pointing device in an east cardinal point direction thrice or by moving the pointing device in an east cardinal point direction once combined with the simultaneous activation of or followed by the sequential activation of the third right position preferred number [#] sensor. Activating the third right position preferred number [#] sensor twice produces an upper-case “O”.

The “p” is produced by moving the pointing device in a south-west cardinal point direction once or by moving the pointing device in a south-west cardinal point direction once combined with the simultaneous activation of or followed by the sequential activation of the first left position preferred asterisk [*] sensor. Activating the first left position preferred asterisk [*] sensor twice produces an upper-case “P”.

The “q” is produced by moving the pointing device in a north-west cardinal point direction twice or by moving the pointing device in a north-west cardinal point direction once combined with the simultaneous activation of or followed by the sequential activation of the second middle position preferred zero [0] sensor. Activating the second middle position preferred zero [0] sensor twice produces an upper-case “Q”.

The “r” is produced by moving the pointing device in a south-west cardinal point direction twice or by moving the pointing device in a south-west cardinal point direction once combined with the simultaneous activation of or followed by the sequential activation of the second middle position preferred zero [0] sensor. Activating the second middle position preferred zero [0] sensor twice produces an upper-case “R”.

The “s” is produced by moving the pointing device in a south-west cardinal point direction thrice or by moving the pointing device in a south-west cardinal point direction once combined with the simultaneous activation of or followed by the sequential activation of the third right position preferred number [#] sensor. Activating the third right position preferred number [#] sensor twice produces an upper-case “S”.

The “t” is produced by moving the pointing device in a south cardinal point direction once or by moving the pointing device in a south cardinal point direction once combined with the simultaneous activation of or followed by the sequential activation of the first left position preferred asterisk [*] sensor. Activating the first left position preferred asterisk [*] sensor twice produces an upper-case “T”.

The “u” is produced by moving the pointing device in a south cardinal point direction twice or by moving the pointing device in a south cardinal point direction once combined with the simultaneous activation of or followed by the sequential activation of the second middle position preferred zero [0] sensor. Activating the second middle position preferred zero [0] sensor twice produces an upper-case “U”.

The “v” is produced by moving the pointing device in a south cardinal point direction thrice or by moving the pointing device in a south cardinal point direction once combined with the simultaneous activation of or followed by the sequential activation of the third right position preferred number [#] sensor. Activating the third right position preferred number [#] sensor twice produces an upper-case “V”.

The “w” is produced by moving the pointing device in a south-east cardinal point direction once or by moving the pointing device in a south-east cardinal point direction once combined with the simultaneous activation of or followed by the sequential activation of the first left position preferred asterisk [*] sensor. Activating the first left position preferred asterisk [*] sensor twice produces an upper-case “W”.

The “x” is produced by moving the pointing device in a south-east cardinal point direction twice or by moving the pointing device in a south-east cardinal point direction once combined with the simultaneous activation of or followed by the sequential activation of the second middle position preferred zero [0] sensor. Activating the second middle position preferred zero [0] sensor twice produces an upper-case “X”.

The “y” is produced by moving the pointing device in a south-east cardinal point direction thrice or by moving the pointing device in a south-east cardinal point direction once combined with the simultaneous activation of or followed by the sequential activation of the third right position preferred number [#] sensor. Activating the third right position preferred number [#] sensor twice produces an upper-case “Y”.

The “z” is produced by moving the pointing device in a north-west cardinal point direction thrice or by moving the pointing device in a north-west cardinal point direction once combined with the simultaneous activation of or followed by the sequential activation of the third right position preferred number [#] sensor. Activating the third right position preferred number [#] sensor twice produces an upper-case “Z”.

The “space” is produced by moving the pointing device in a north-west cardinal point direction once, by moving the pointing device in a north-west cardinal point direction once combined with the simultaneous activation of or followed by the sequential activation of the first left position preferred asterisk [*] sensor or by activating the second middle position preferred zero [0] sensor once.

The “1” is produced by moving the pointing device in a north-west cardinal point direction four times.

The “2” is produced by moving the pointing device in a north cardinal point direction four times.

The “3” is produced by moving the pointing device in a north-east cardinal point direction four times.

The “4” is produced by moving the pointing device in a west cardinal point direction four times.

The “5” is produced by moving the pointing device downward four times.

The “6” is produced by moving the pointing device in an east cardinal point direction four times.

The “7” is produced by moving the pointing device in a south-west cardinal point direction four times.

The “8” is produced by moving the pointing device in a south cardinal point direction four times.

The “9” is produced by moving the pointing device in a south-east cardinal point direction four times.

The question mark “?” is produced by moving the pointing device in a north-west cardinal point direction five times.

The comma “,” is produced by moving the pointing device in a north cardinal point direction five times.

The exclamation mark “!” is produced by moving the pointing device in a north-east cardinal point direction five times.

The hyphen “-” is produced by moving the pointing device in a west cardinal point direction five times.

The semicolon “;” is produced by moving the pointing device downward five times.

The zero “0” is produced by moving the pointing device in an east cardinal point direction five times.

The period “.” is produced by moving the pointing device in a south-west cardinal point direction five times.

The colon “:” is produced by moving the pointing device in a south cardinal point direction five times.

The number sign “#” is produced by moving the pointing device in a south-east cardinal point direction five times.

The ampersand “&” is produced by moving the pointing device in a north-west cardinal point direction six times.

The at sign “@” is produced by moving the pointing device in a north cardinal point direction six times.

The dollar sign “$” is produced by moving the pointing device in a north-east cardinal point direction six times.

The backslash “\” is produced by moving the pointing device in a west cardinal point direction six times.

The underscore “_” is produced by moving the pointing device downward six times.

The slash “/” is produced by moving the pointing device in an east cardinal point direction six times.

The left parenthesis “(” is produced by moving the pointing device in a south-west cardinal point direction six times.

The vertical line “|” is produced by moving the pointing device in a south cardinal point direction six times.

The right parenthesis “)” is produced by moving the pointing device in a south-east cardinal point direction six times.

The quote ““ ” is produced by moving the pointing device in a north-west cardinal point direction seven times.

The apostrophe “'” is produced by moving the pointing device in a north cardinal point direction seven times.

The equals sign “=” is produced by moving the pointing device in a north-east cardinal point direction seven times.

The asterisk “*” is produced by moving the pointing device in a west cardinal point direction seven times.

The percent sign “%” is produced by moving the pointing device downward seven times.

The plus sign “+” is produced by moving the pointing device in an east cardinal point direction seven times.

The less than sign “<” is produced by moving the pointing device in a south-west cardinal point direction seven times.

The tilde “˜” is produced by moving the pointing device in a south cardinal point direction seven times.

The greater than sign “>” is produced by moving the pointing device in a south-east cardinal point direction seven times.

Moving the pointing device in eight cardinal point directions or downward eight times or more produces even more data characters, control or functions. Programming the device to produce the user's preferred data characters using preferred key activations is also possible.

Another preferred embodiment of the present invention includes:

A method of using a pointing device for producing numbers one through nine, at least twenty-six data characters or letters of an alphabet and a space, punctuation and symbols. Moving the pointing device in eight cardinal point directions or downward once produces numbers one through nine, twice produces the first preferably left position data, thrice produces the second preferably middle position data and four times produces the third preferably right position data, etc. Alternatively, moving the pointing device in eight cardinal point directions or downward combined with the simultaneous activation of or followed by the sequential activation of a first left position preferred asterisk [*] sensor produces the first preferably left position data, activation of a second middle position preferred zero [0] sensor produces the second preferably middle position data, or activation of a third right position preferred number [#] sensor produces the third preferably right position data. Secondary activation of the second activated sensor produces an upper-case letter.

The “1” is produced by moving the pointing device in a north-west cardinal point direction once.

The “2” is produced by moving the pointing device in a north cardinal point direction once.

The “3” is produced by moving the pointing device in a north-east cardinal point direction once.

The “4” is produced by moving the pointing device in a west cardinal point direction once.

The “5” is produced by moving the pointing device downward once.

The “6” is produced by moving the pointing device in an east cardinal point direction once.

The “7” is produced by moving the pointing device in a south-west cardinal point direction once.

The “8” is produced by moving the pointing device in a south cardinal point direction once.

The “9” is produced by moving the pointing device in a south-east cardinal point direction once.

The “a” is produced by moving the pointing device in a north cardinal point direction twice or by moving the pointing device in a north cardinal point direction once combined with the simultaneous activation of or followed by the sequential activation of the first left position preferred asterisk [*] sensor. Activating the first left position preferred asterisk [*] sensor twice produces an upper-case “A”.

The “b” is produced by moving the pointing device in a north cardinal point direction thrice or by moving the pointing device in a north cardinal point direction once combined with the simultaneous activation of or followed by the sequential activation of the second middle position preferred zero [0] sensor. Activating the second middle position preferred zero [0] sensor twice produces an upper-case “B”.

The “c” is produced by moving the pointing device in a north cardinal point direction four times or by moving the pointing device in a north cardinal point direction once combined with the simultaneous activation of or followed by the sequential activation of the third right position preferred number [#] sensor. Activating the third right position preferred number [#] sensor twice produces an upper-case “C”.

The “d” is produced by moving the pointing device in a north-east cardinal point direction twice or by moving the pointing device in a north-east cardinal point direction once combined with the simultaneous activation of or followed by the sequential activation of the first left position preferred asterisk [*] sensor. Activating the first left position preferred asterisk [*] sensor twice produces an upper-case “D”.

The “e” is produced by moving the pointing device in a north-east cardinal point direction thrice or by moving the pointing device in a north-east cardinal point direction once combined with the simultaneous activation of or followed by the sequential activation of the second middle position preferred zero [0] sensor. Activating the second middle position preferred zero [0] sensor twice produces an upper-case “E”.

The “f” is produced by moving the pointing device in a north-east cardinal point direction four times or by moving the pointing device in a north-east cardinal point direction once combined with the simultaneous activation of or followed by the sequential activation of the third right position preferred number [#] sensor. Activating the third right position preferred number [#] sensor twice produces an upper-case “F”.

The “g” is produced by moving the pointing device in a west cardinal point direction twice or by moving the pointing device in a west cardinal point direction once combined with the simultaneous activation of or followed by the sequential activation of the first left position preferred asterisk [*] sensor. Activating the first left position preferred asterisk [*] sensor twice produces an upper-case “G”.

The “h” is produced by moving the pointing device in a west cardinal point direction thrice or by moving the pointing device in a west cardinal point direction once combined with the simultaneous activation of or followed by the sequential activation of the second middle position preferred zero [0] sensor. Activating the second middle position preferred zero [0] sensor twice produces an upper-case “H”.

The “i” is produced by moving the pointing device in a west cardinal point direction four times or by moving the pointing device in a west cardinal point direction once combined with the simultaneous activation of or followed by the sequential activation of the third right position preferred number [#] sensor. Activating the third right position preferred number [#] sensor twice produces an upper-case “I”.

The “j” is produced by moving the pointing device downward twice or by moving the pointing device downward once combined with the simultaneous activation of or followed by the sequential activation of the right preferred asterisk [*] sensor. Activating the first left position preferred asterisk [*] sensor twice produces an upper-case “J”.

The “k” is produced by moving the pointing device downward thrice or by moving the pointing device downward once combined with the simultaneous activation of or followed by the sequential activation of the right preferred zero [0] sensor. Activating the second middle position preferred zero [0] sensor twice produces an upper-case “K”.

The “I” is produced by moving the pointing device downward four times or by moving the pointing device downward once combined with the simultaneous activation of or followed by the sequential activation of the third right position preferred number [#] sensor. Activating the third right position preferred number [#] sensor twice produces an upper-case “L”.

The “m” is produced by moving the pointing device in an east cardinal point direction twice or by moving the pointing device in an east cardinal point direction once combined with the simultaneous activation of or followed by the sequential activation of the first left position preferred asterisk [*] sensor. Activating the first left position preferred asterisk [*] sensor twice produces an upper-case “M”.

The “n” is produced by moving the pointing device in an east cardinal point direction thrice or by moving the pointing device in an east cardinal point direction once combined with the simultaneous activation of or followed by the sequential activation of the second middle position preferred zero [0] sensor. Activating the second middle position preferred zero [0] sensor twice produces an upper-case “N”.

The “o” is produced by moving the pointing device in an east cardinal point direction four times or by moving the pointing device in an east cardinal point direction once combined with the simultaneous activation of or followed by the sequential activation of the third right position preferred number [#] sensor. Activating the third right position preferred number [#] sensor twice produces an upper-case “O”.

The “p” is produced by moving the pointing device in a south-west cardinal point direction twice or by moving the pointing device in a south-west cardinal point direction once combined with the simultaneous activation of or followed by the sequential activation of the first left position preferred asterisk [*] sensor. Activating the first left position preferred asterisk [*] sensor twice produces an upper-case “P”.

The “q” is produced by moving the pointing device in a north-west cardinal point direction thrice or by moving the pointing device in a north-west cardinal point direction once combined with the simultaneous activation of or followed by the sequential activation of the second middle position preferred zero [0] sensor. Activating the second middle position preferred zero [0] sensor twice produces an upper-case “Q”.

The “r” is produced by moving the pointing device in a south-west cardinal point direction thrice or by moving the pointing device in a south-west cardinal point direction once combined with the simultaneous activation of or followed by the sequential activation of the second middle position preferred zero [0] sensor. Activating the second middle position preferred zero [0] sensor twice produces an upper-case “R”.

The “s” is produced by moving the pointing device in a south-west cardinal point direction four times or by moving the pointing device in a south-west cardinal point direction once combined with the simultaneous activation of or followed by the sequential activation of the third right position preferred number [#] sensor. Activating the third right position preferred number [#] sensor twice produces an upper-case “S”.

The “t” is produced by moving the pointing device in a south cardinal point direction twice or by moving the pointing device in a south cardinal point direction once combined with the simultaneous activation of or followed by the sequential activation of the first left position preferred asterisk [*] sensor. Activating the first left position preferred asterisk [*] sensor twice produces an upper-case “T”.

The “u” is produced by moving the pointing device in a south cardinal point direction thrice or by moving the pointing device in a south cardinal point direction once combined with the simultaneous activation of or followed by the sequential activation of the second middle position preferred zero [0] sensor. Activating the second middle position preferred zero [0] sensor twice produces an upper-case “U”.

The “v” is produced by moving the pointing device in a south cardinal point direction four times or by moving the pointing device in a south cardinal point direction once combined with the simultaneous activation of or followed by the sequential activation of the third right position preferred number [#] sensor. Activating the third right position preferred number [#] sensor twice produces an upper-case “V”.

The “w” is produced by moving the pointing device in a south-east cardinal point direction twice or by moving the pointing device in a south-east cardinal point direction once combined with the simultaneous activation of or followed by the sequential activation of the first left position preferred asterisk [*] sensor. Activating the first left position preferred asterisk [*] sensor twice produces an upper-case “W”.

The “x” is produced by moving the pointing device in a south-east cardinal point direction thrice or by moving the pointing device in a south-east cardinal point direction once combined with the simultaneous activation of or followed by the sequential activation of the second middle position preferred zero [0] sensor. Activating the second middle position preferred zero [0] sensor twice produces an upper-case “X”.

The “y” is produced by moving the pointing device in a south-east cardinal point direction four times or by moving the pointing device in a south-east cardinal point direction once combined with the simultaneous activation of or followed by the sequential activation of the third right position preferred number [#] sensor. Activating the third right position preferred number [#] sensor twice produces an upper-case “Y”.

The “z” is produced by moving the pointing device in a north-west cardinal point direction four times or by moving the pointing device in a north-west cardinal point direction once combined with the simultaneous activation of or followed by the sequential activation of the third right position preferred number [#] sensor. Activating the third right position preferred number [#] sensor twice produces an upper-case “Z”.

The “space” is produced by moving the pointing device in a north-west cardinal point direction twice, by moving the pointing device in a north-west cardinal point direction once combined with the simultaneous activation of or followed by the sequential activation of the first left position preferred asterisk [*] sensor or by activating the second middle position preferred zero [0] sensor once.

The question mark “?” is produced by moving the pointing device in a north-west cardinal point direction five times.

The comma “,” is produced by moving the pointing device in a north cardinal point direction five times.

The exclamation mark “!” is produced by moving the pointing device in a north-east cardinal point direction five times.

The hyphen “-” is produced by moving the pointing device in a west cardinal point direction five times.

The semicolon “;” is produced by moving the pointing device downward five times.

The zero “0” is produced by moving the pointing device in an east cardinal point direction five times.

The period “.” is produced by moving the pointing device in a south-west cardinal point direction five times.

The colon “:” is produced by moving the pointing device in a south cardinal point direction five times.

The number sign “#” is produced by moving the pointing device in a south-east cardinal point direction five times.

The ampersand “&” is produced by moving the pointing device in a north-west cardinal point direction six times.

The at sign “@” is produced by moving the pointing device in a north cardinal point direction six times.

The dollar sign “$” is produced by moving the pointing device in a north-east cardinal point direction six times.

The backslash “\” is produced by moving the pointing device in a west cardinal point direction six times. The underscore “_” is produced by moving the pointing device downward six times.

The slash “/” is produced by moving the pointing device in an east cardinal point direction six times.

The left parenthesis “(” is produced by moving the pointing device in a south-west cardinal point direction six times.

The vertical line “|” is produced by moving the pointing device in a south cardinal point direction six times.

The right parenthesis “)” is produced by moving the pointing device in a south-east cardinal point direction six times.

The quote ““” is produced by moving the pointing device in a north-west cardinal point direction seven times.

The apostrophe “'” is produced by moving the pointing device in a north cardinal point direction seven times.

The equals sign “=” is produced by moving the pointing device in a north-east cardinal point direction seven times.

The asterisk “*” is produced by moving the pointing device in a west cardinal point direction seven times.

The percent sign “%” is produced by moving the pointing device downward seven times.

The plus sign “+” is produced by moving the pointing device in an east cardinal point direction seven times.

The less than sign “<” is produced by moving the pointing device in a south-west cardinal point direction seven times.

The tilde “˜” is produced by moving the pointing device in a south cardinal point direction seven times.

The greater than sign “>” is produced by moving the pointing device in a south-east cardinal point direction seven times.

Moving the pointing device in eight cardinal point directions or downward eight times or more produces even more data characters, control or functions. Programming the device to produce the user's preferred data characters using preferred key activations is also possible.

Another preferred embodiment of the present invention includes:

A method of using a pointing device for producing numbers one through nine, at least twenty-six data characters or letters of an alphabet and a space, punctuation and symbols. Moving the pointing device in eight cardinal point directions or downward once produces numbers one through nine. Alternatively, moving the pointing device in eight cardinal point directions or downward once combined with the simultaneous activation of or followed by the sequential activation of a first left position preferred asterisk [*] sensor produces the first preferably left position data, activation of a second middle position preferred zero [0] sensor produces the second preferably middle position data, or activation of a third right position preferred number [#] sensor produces the third preferably right position data. Secondary activation of the second activated sensor produces an upper-case letter. Moving the pointing device in eight cardinal point directions or downward combined with the simultaneous activation of or followed by the sequential activation of a first left position sensor ([1], [4] or [7]) produces the left position data, activation of a second middle position sensor ([2], [5] or [8]) produces the middle position data, or activation of a third right position sensor ([3], [6] or [9]) produces the right position data.

The “1” is produced by moving the pointing device in a north-west cardinal point direction once.

The “2” is produced by moving the pointing device in a north cardinal point direction once.

The “3” is produced by moving the pointing device in a north-east cardinal point direction once.

The “4” is produced by moving the pointing device in a west cardinal point direction once.

The “5” is produced by moving the pointing device downward once.

The “6” is produced by moving the pointing device in an east cardinal point direction once.

The “7” is produced by moving the pointing device in a south-west cardinal point direction once.

The “8” is produced by moving the pointing device in a south cardinal point direction once.

The “9” is produced by moving the pointing device in a south-east cardinal point direction once.

The “a” is produced by moving the pointing device in a north cardinal point direction combined with the simultaneous activation of or followed by the sequential activation of the first left position preferred asterisk [*] sensor. Activating the first left position preferred asterisk [*] sensor twice produces an upper-case “A”.

The “b” is produced by moving the pointing device in a north cardinal point direction combined with the simultaneous activation of or followed by the sequential activation of the second middle position preferred zero [0] sensor. Activating the second middle position preferred zero [0] sensor twice produces an upper-case “B”.

The “c” is produced by moving the pointing device in a north cardinal point direction combined with the simultaneous activation of or followed by the sequential activation of the third right position preferred number [#] sensor. Activating the third right position preferred number [#] sensor twice produces an upper-case “C”.

The “d” is produced by moving the pointing device in a north-east cardinal point direction combined with the simultaneous activation of or followed by the sequential activation of the first left position preferred asterisk [*] sensor. Activating the first left position preferred asterisk [*] sensor twice produces an upper-case “D”.

The “e” is produced by moving the pointing device in a north-east cardinal point direction combined with the simultaneous activation of or followed by the sequential activation of the second middle position preferred zero [0] sensor. Activating the second middle position preferred zero [0] sensor twice produces an upper-case “E”.

The “f” is produced by moving the pointing device in a north-east cardinal point direction combined with the simultaneous activation of or followed by the sequential activation of the third right position preferred number [#] sensor. Activating the third right position preferred number [#] sensor twice produces an upper-case “F”.

The “g” is produced by moving the pointing device in a west cardinal point direction combined with the simultaneous activation of or followed by the sequential activation of the first left position preferred asterisk [*] sensor. Activating the first left position preferred asterisk [*] sensor twice produces an upper-case “G”.

The “h” is produced by moving the pointing device in a west cardinal point direction combined with the simultaneous activation of or followed by the sequential activation of the second middle position preferred zero [0] sensor. Activating the second middle position preferred zero [0] sensor twice produces an upper-case “H”.

The “i” is produced by moving the pointing device in a west cardinal point direction combined with the simultaneous activation of or followed by the sequential activation of the third right position preferred number [#] sensor. Activating the third right position preferred number [#] sensor twice produces an upper-case “I”.

The “j” is produced by moving the pointing device downward combined with the simultaneous activation of or followed by the sequential activation of the right preferred asterisk [*] sensor. Activating the first left position preferred asterisk [*] sensor twice produces an upper-case “J”.

The “k” is produced by moving the pointing device downward combined with the simultaneous activation of or followed by the sequential activation of the right preferred zero [0] sensor. Activating the second middle position preferred zero [0] sensor twice produces an upper-case “K”.

The “i” is produced by moving the pointing device downward combined with the simultaneous activation of or followed by the sequential activation of the third right position preferred number [#] sensor. Activating the third right position preferred number [#] sensor twice produces an upper-case “L”.

The “m” is produced by moving the pointing device in an east cardinal point direction combined with the simultaneous activation of or followed by the sequential activation of the first left position preferred asterisk [*] sensor. Activating the first left position preferred asterisk [*] sensor twice produces an upper-case “M”.

The “n” is produced by moving the pointing device in an east cardinal point direction combined with the simultaneous activation of or followed by the sequential activation of the second middle position preferred zero [0] sensor. Activating the second middle position preferred zero [0] sensor twice produces an upper-case “N”.

The “o” is produced by moving the pointing device in an east cardinal point direction combined with the simultaneous activation of or followed by the sequential activation of the third right position preferred number [#] sensor. Activating the third right position preferred number [#] sensor twice produces an upper-case “O”.

The “p” is produced by moving the pointing device in a south-west cardinal point direction combined with the simultaneous activation of or followed by the sequential activation of the first left position preferred asterisk [*] sensor. Activating the first left position preferred asterisk [*] sensor twice produces an upper-case “P”.

The “q” is produced by moving the pointing device in a north-west cardinal point direction combined with the simultaneous activation of or followed by the sequential activation of the second middle position preferred zero [0] sensor. Activating the second middle position preferred zero [0] sensor twice produces an upper-case “Q”.

The “r” is produced by moving the pointing device in a south-west cardinal point direction combined with the simultaneous activation of or followed by the sequential activation of the second middle position preferred zero [0] sensor. Activating the second middle position preferred zero [0] sensor twice produces an upper-case “R”.

The “s” is produced by moving the pointing device in a south-west cardinal point direction combined with the simultaneous activation of or followed by the sequential activation of the third right position preferred number [#] sensor. Activating the third right position preferred number [#] sensor twice produces an upper-case “S”.

The “t” is produced by moving the pointing device in a south cardinal point direction combined with the simultaneous activation of or followed by the sequential activation of the first left position preferred asterisk [*] sensor. Activating the first left position preferred asterisk [*] sensor twice produces an upper-case “T”.

The “u” is produced by moving the pointing device in a south cardinal point direction combined with the simultaneous activation of or followed by the sequential activation of the second middle position preferred zero [0] sensor. Activating the second middle position preferred zero [0] sensor twice produces an upper-case “U”.

The “v” is produced by moving the pointing device in a south cardinal point direction combined with the simultaneous activation of or followed by the sequential activation of the third right position preferred number [#] sensor. Activating the third right position preferred number [#] sensor twice produces an upper-case “V”.

The “w” is produced by moving the pointing device in a south-east cardinal point direction combined with the simultaneous activation of or followed by the sequential activation of the first left position preferred asterisk [*] sensor. Activating the first left position preferred asterisk [*] sensor twice produces an upper-case “W”.

The “x” is produced by moving the pointing device in a south-east cardinal point direction combined with the simultaneous activation of or followed by the sequential activation of the second middle position preferred zero [0] sensor. Activating the second middle position preferred zero [0] sensor twice produces an upper-case “X”.

The “y” is produced by moving the pointing device in a south-east cardinal point direction combined with the simultaneous activation of or followed by the sequential activation of the third right position preferred number [#] sensor. Activating the third right position preferred number [#] sensor twice produces an upper-case “Y”.

The “z” is produced by moving the pointing device in a north-west cardinal point direction combined with the simultaneous activation of or followed by the sequential activation of the third right position preferred number [#] sensor. Activating the third right position preferred number [#] sensor twice produces an upper-case “Z”.

The “space” is produced by moving the pointing device in a north-west cardinal point direction combined with the simultaneous activation of or followed by the sequential activation of the first left position preferred asterisk [*] sensor or by activating the second middle position preferred zero [0] sensor once.

The question mark “?” is produced by moving the pointing device in a north-west cardinal point direction combined with the simultaneous activation of or followed by the sequential activation of a left [1], [4] or [7] sensor.

The comma “,” is produced by moving the pointing device in a north cardinal point direction combined with the simultaneous activation of or followed by the sequential activation of a left [1], [4] or [7] sensor.

The exclamation mark “!” is produced by moving the pointing device in a north-east cardinal point direction combined with the simultaneous activation of or followed by the sequential activation of a left [1 ], [4] or [7] sensor.

The hyphen “-” is produced by moving the pointing device in a west cardinal point direction combined with the simultaneous activation of or followed by the sequential activation of a left [1], [4] or [7] sensor.

The semicolon “;” is produced by moving the pointing device downward combined with the simultaneous activation of or followed by the sequential activation of a left [1], [4] or [7] sensor.

The zero “0” is produced by moving the pointing device in an east cardinal point direction combined with the simultaneous activation of or followed by the sequential activation of a left [1], [4] or [7] sensor.

The period “.” is produced by moving the pointing device in a south-west cardinal point direction combined with the simultaneous activation of or followed by the sequential activation of a left [1], [4] or [7] sensor.

The colon “:” is produced by moving the pointing device in a south cardinal point direction combined with the simultaneous activation of or followed by the sequential activation of a left [1], [4] or [7] sensor.

The number sign “#” is produced by moving the pointing device in a south-east cardinal point direction combined with the simultaneous activation of or followed by the sequential activation of a left [1], [4] or [7] sensor.

The ampersand “&” is produced by moving the pointing device in a north-west cardinal point direction combined with the simultaneous activation of or followed by the sequential activation of a middle [2], [5] or [8] sensor.

The at sign “@” is produced by moving the pointing device in a north cardinal point direction combined with the simultaneous activation of or followed by the sequential activation of a middle [2], [5] or [8] sensor.

The dollar sign “$” is produced by moving the pointing device in a north-east cardinal point direction combined with the simultaneous activation of or followed by the sequential activation of a middle [2], [5] or [8] sensor.

The backslash “\” is produced by moving the pointing device in a west cardinal point direction combined with the simultaneous activation of or followed by the sequential activation of a middle [2], [5] or [8] sensor.

The underscore “_” is produced by moving the pointing device downward combined with the simultaneous activation of or followed by the sequential activation of a middle [2], [5] or [8] sensor.

The slash “/” is produced by moving the pointing device in an east cardinal point direction combined with the simultaneous activation of or followed by the sequential activation of a middle [2], [5] or [8] sensor.

The left parenthesis “(” is produced by moving the pointing device in a south-west cardinal point direction combined with the simultaneous activation of or followed by the sequential activation of a middle [2], [5] or [8] sensor.

The vertical line “|” is produced by moving the pointing device in a south cardinal point direction combined with the simultaneous activation of or followed by the sequential activation of a middle [2], [5] or [8] sensor.

The right parenthesis “)” is produced by moving the pointing device in a south-east cardinal point direction combined with the simultaneous activation of or followed by the sequential activation of a middle [2], [5] or [8] sensor.

The quote ““” is produced by moving the pointing device in a north-west cardinal point direction combined with the simultaneous activation of or followed by the sequential activation of a right [3], [6] or [9] sensor.

The apostrophe “'” is produced by moving the pointing device in a north cardinal point direction combined with the simultaneous activation of or followed by the sequential activation of a right [3], [6] or [9] sensor.

The equals sign “=” is produced by moving the pointing device in a north-east cardinal point direction combined with the simultaneous activation of or followed by the sequential activation of a right [3], [6] or [9] sensor.

The asterisk “*” is produced by moving the pointing device in a west cardinal point direction combined with the simultaneous activation of or followed by the sequential activation of a right [3], [6] or [9] sensor.

The percent sign “%” is produced by moving the pointing device downward combined with the simultaneous activation of or followed by the sequential activation of a right [3], [6] or [9] sensor.

The plus sign “+” is produced by moving the pointing device in an east cardinal point direction combined with the simultaneous activation of or followed by the sequential activation of a right [3], [6] or [9] sensor.

The less than sign “<” is produced by moving the pointing device in a south-west cardinal point direction combined with the simultaneous activation of or followed by the sequential activation of a right [3], [6] or [9] sensor.

The tilde “˜” is produced by moving the pointing device in a south cardinal point direction combined with the simultaneous activation of or followed by the sequential activation of a right [3], [6] or [9] sensor.

The greater than sign “>” is produced by moving the pointing device in a south-east cardinal point direction combined with the simultaneous activation of or followed by the sequential activation of a right [3], [6] or [9] sensor.

Moving the pointing device in eight cardinal point directions or downward more than once produces even more data characters, punctuation marks, symbols, control or functions. Programming the device to produce the user's preferred data characters using preferred key activations is also possible.

Alternatively, any letter data, numeric data, punctuation data, symbol data or any other type of data or character substitution can be made or used for the present invention's described text input methods and alternative preferred embodiments.

In another preferred embodiment of the present invention, when using the pointing device in eight cardinal point directions or downward to produce data on a device, activating any sensor other than the pointing device enters the entered data for the production of the next data character located on the same sensor as the previously entered data character.

In another preferred embodiment of the present invention, moving the pointing device in eight cardinal point directions or downward combined with the simultaneous activation of or followed by the sequential activation of a left preferred [1], [4], [7] or [*] sensor produces the first preferably left position data, activation of a middle preferred [2], [5], [8] or [0] sensor produces the second preferably middle position data, or activation of a right preferred [3], [6], [9] or [#] sensor produces the third preferably right position data.

In another preferred embodiment of the present invention, when using the pointing device in eight cardinal point directions or downward to produce data on a device or cell phone, activating the first left position preferred asterisk [*] sensor when using only the pointing device in eight cardinal point directions or downward to produce alphabetic data, while in an alphabetic multi-tap mode, produces an upper-case data character.

In another preferred embodiment of the present invention, when using the pointing device in eight cardinal point directions or downward to produce data on a device or cell phone, activating the first left position preferred asterisk [*] sensor once produces a period “.”, activating the second middle position preferred zero [0] sensor once produces a space “ ”, activating the third right position preferred number [#] sensor once produces a hyphen “-”.

In another preferred embodiment of the present invention, numbers are produced by activating one of the ten numbered sensors. In another preferred embodiment of the present invention, to produce a backspace while in the number mode, the third right position preferred number [#] sensor is activated once, when it is not followed by the sequential activation of a first left preferred asterisk [*] sensor or a second middle preferred zero [0] sensor.

In another preferred embodiment of the present invention, activation of the third right position preferred number [#] sensor three times, while in the alphanumeric mode, produces the “ENTER/RETURN/SEND” function.

In another preferred embodiment of the present invention, activation of the first left position preferred asterisk [*] sensor, while in the number mode, when not followed by the sequential activation of middle preferred zero [0] sensor or the activation of the third right position preferred number [#] sensor, exits the number mode and enters an alphabet mode.

In another preferred embodiment of the present invention, activation of the first left position preferred asterisk [*] sensor followed by the secondary activation of the first left position preferred asterisk [*] sensor, when not followed by the sequential activation of middle preferred zero [0] sensor or the activation of the third right position preferred number [#] sensor, while in the number mode, exits the number mode and enters a two sensor lower-case alphabet mode and a three sensor upper-case alphabet mode, where the secondary activation of the second activated sensor produces the upper-case character.

In another preferred embodiment of the present invention, activation of the second middle position preferred zero [0] sensor two times, while in an alphabetic mode, produces the “TAB” function.

In another preferred embodiment of the present invention, activation of the first left position preferred asterisk [*] sensor, while in an alphabetic mode, followed by the first left position preferred asterisk [*] sensor, deletes the previously-entered bit of data, otherwise known as the backspace.

In another preferred embodiment of the present invention, activation of the first left position preferred asterisk [*] sensor three times, while in an alphabetic mode, deletes the previously entered word.

In another preferred embodiment of the present invention, activation of the first left position preferred asterisk [*] sensor, while in an alphabetic mode, combined with the simultaneous activation of or followed by the sequential activation of the second middle position preferred zero [0] sensor produces a period “•”.

In another preferred embodiment of the present invention, activation of the first left position preferred asterisk [*] sensor, while in the alphabetic mode, combined with the simultaneous activation of or followed by the sequential activation of the activation of the third right position preferred number [#] sensor enters a one-time use punctuation mode, followed by the desired punctuation data sensor representation of the ten sensors numbered one [1] through zero [0], where the activation of the preferred [1] sensor produces a question mark “?”, where the activation of the preferred [2] sensor produces a comma “,”, where the activation of the preferred [3] sensor produces an exclamation mark “!”, where the activation of the preferred [4] sensor produces a hyphen “-”, where the activation of the preferred [5] sensor produces a semicolon “;”, where the activation of the preferred [6] sensor produces a zero “0”, where the activation of the preferred [7] sensor produces a period “•”, where the activation of the preferred [8] sensor produces a colon “:”, where the activation of the preferred [9] sensor produces a number sign “#”, where the activation of the preferred [0] sensor produces an at sign “@”. After producing a punctuation mark the device returns to the previous alphabetic mode.

In another preferred embodiment of the present invention, activation of the third right position preferred number [#] sensor combined with the simultaneous activation of or followed by the sequential activation of the second middle position preferred zero [0] sensor, while in the alphabetic mode, returns the keyboard to the number mode.

These and other features of the present invention will be more fully understood by referencing the drawings.

In summary, the present invention and many preferred embodiments of the present invention all use a pointing device in eight cardinal point directions or downward to produce alphabetic data characters, data characters, a space, numbers, punctuation, symbols, control and functions, preferably activated by the left or right thumb. The pointing device in eight cardinal point directions or downward, activated by one digit on a user's hand, is the smallest keyboard in the history of mankind and fulfills the need for blind text messaging and one handed text messaging. Three or six additional sensors provide a reduction in the number of key activations and increased data entry speed for producing simultaneous or sequential sensor activations.

While the present invention disclosed has been described with reference to the preferred embodiments thereof, a latitude of modification, change, and substitution is intended in the foregoing disclosure, and in some instances, some features of the invention will be employed without a corresponding use of the inventions other features. Accordingly, it will be appreciated by those having an ordinary skill in the art that various modifications can be made to the system of the invention and it is appropriate that the description and appended claims are construed broadly and in a manner consistent with the spirit and scope of the invention herein without departing from the spirit and scope of the invention as a whole.

1. An alphanumeric keyboard comprising:
a pointing device having a means for moving in one of eight cardinal point directions or in a downward direction to produce alphanumeric data, a space or other types of data.

2. An alphanumeric keyboard, in accordance with claim 1, wherein:
moving said pointing device once in one of said eight cardinal point directions or in said downward direction produces a number one through nine.

3. An alphanumeric keyboard, in accordance with claim 1, wherein:
moving said pointing device four times in one of said eight cardinal point directions or in said downward direction produces a number one through nine.

4. An alphanumeric keyboard, in accordance with claim 1, wherein:
moving said pointing device one or more times in one of said eight cardinal point directions or in said downward direction produces one of twenty-six data characters or a space.

5. An alphanumeric keyboard, in accordance with claim 1, wherein:
moving said pointing device more than once in one of said eight cardinal point directions or in said downward direction produces a zero, a punctuation mark or a symbol.

6. An alphanumeric keyboard, in accordance with claim 1, wherein:
moving said pointing device once in one of said eight cardinal point directions or in said downward direction produces one of twenty-six data characters or a space when sequentially or simultaneously activated with one sensor of three additional sensors.

7. An alphanumeric keyboard, in accordance with claim 1, wherein:
moving said pointing device once in one of said eight cardinal point directions or in said downward direction produces a zero, a punctuation mark or a symbol when sequentially or simultaneously activated with one sensor of three additional sensors.

8. An alphanumeric keyboard, in accordance with claim 1, wherein:
a) moving said pointing device once in one of said eight cardinal point directions or in said downward direction produces a number one through nine; and
b) moving said pointing device once in one of said eight cardinal point directions or in said downward direction produces one of twenty-six data characters or a space when sequentially or simultaneously activated with one sensor of three additional sensors.

9. An alphanumeric keyboard, in accordance with claim 1, wherein:
a) moving said pointing device once in one of said eight cardinal point directions or in said downward direction produces a number one through nine; and
b) moving said pointing device once in one of said eight cardinal point directions or in said downward direction produces a zero, a punctuation mark or a symbol when sequentially or simultaneously activated with one sensor of three additional sensors.

10. An alphanumeric keyboard comprising:
a 360° directional movement pointing device having a means for moving in one of eight cardinal point directions or in a downward direction to produce alphanumeric data, a space or other types of data.

11. An alphanumeric keyboard, in accordance with claim 10, wherein:
moving said 360° directional movement pointing device once in one of said eight cardinal point directions or in said downward direction produces a number one through nine.

12. An alphanumeric keyboard, in accordance with claim 10, wherein:
moving said 360° directional movement pointing device four times in one of said eight cardinal point directions or in said downward direction produces a number one through nine.

13. An alphanumeric keyboard, in accordance with claim 10, wherein:
moving said 360° directional movement pointing device one or more times in one of said eight cardinal point directions or in said downward direction produces one of twenty-six data characters or a space.

14. An alphanumeric keyboard, in accordance with claim 10, wherein:
moving said 360° directional movement pointing device more than once in one of said eight cardinal point directions or in said downward direction produces a zero, a punctuation mark or a symbol.

15. An alphanumeric keyboard, in accordance with claim 10, wherein:
moving said 360° directional movement pointing device once in one of said eight cardinal point directions or in said downward direction produces one of twenty-six data characters or a space when sequentially or simultaneously activated with one sensor of three additional sensors.

16. An alphanumeric keyboard, in accordance with claim 10, wherein:
moving said 360° directional movement pointing device once in one of said eight cardinal point directions or in said downward direction produces a zero, a punctuation mark or a symbol when sequentially or simultaneously activated with one sensor of three additional sensors.

17. An alphanumeric keyboard, in accordance with claim 10, wherein:
a) moving said 360° directional movement pointing device once in one of said eight cardinal point directions or in said downward direction produces a number one through nine; and
b) moving said 360° directional movement pointing device once in one of said eight cardinal point directions or in said downward direction produces one of twenty-six data characters or a space when sequentially or simultaneously activated with one sensor of three additional sensors.

18. An alphanumeric keyboard, in accordance with claim 10, wherein:
a) moving said 360° directional movement pointing device once in one of said eight cardinal point directions or in said downward direction produces a number one through nine; and
b) moving said 360° directional movement pointing device once in one of said eight cardinal point directions or in said downward direction produces a zero, a punctuation mark or a symbol when sequentially or simultaneously activated with one sensor of three additional sensors.

19. An alphanumeric keyboard comprising:
a) a pointing device having a means for moving in one of eight cardinal point directions or in a downward direction to produce a number one through nine; and
b) moving said pointing device in one of said eight cardinal point directions or in said downward direction when sequentially or simultaneously activated with one sensor of a first set of three additional sensors produces one of twenty-six data characters or a space; and
c) moving said pointing device in one of said eight cardinal point directions or in said downward direction when sequentially or simultaneously activated with one sensor of a second set of three additional sensors produces a zero, a punctuation mark or a symbol.

20. An alphanumeric keyboard, in accordance with claim 19, wherein:
a) any one sensor of said first set of three additional sensors or said second set of three additional sensors is used to produce a data character, a null state or a function; and
b) any one sensor of said first set of three additional sensors sequentially or simultaneously activated with a second sensor of said first set of three additional sensors is used to produce a data character, a null state or a function; and
c) any one sensor of said second set of three additional sensors is used to produce a data character, a null state or a function; and
d) any one sensor of said second set of three additional sensors sequentially or simultaneously activated with a second sensor of said second set of three additional sensors is used to produce a data character, a null state or a function.
